(19) United States
(12) Patent Application Publication
(10) Pub. No.: US 2009/0167974 A1
(43) Pub. Date: Jul. 2, 2009

(54) DISPLAY SUBSTRATE, DISPLAY DEVICE INCLUDING THE DISPLAY SUBSTRATE AND METHOD OF FABRICATING THE DISPLAY SUBSTRATE

(75) Inventors: Jae-ho CHOI, Seoul (KR); Sung-hoon YANG, Seoul (KR); Kap-soo YOON, Seoul (KR); Sung-ryul KIM, Cheonan-si (KR); Hwa-yeul OH, Seoul (KR); Yong-mo CHOI, Osan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/261,470

(22) Filed: Oct. 30, 2008

(30) Foreign Application Priority Data
Dec. 26, 2007 (KR) 10-2007-0137605

(51) Int. Cl. G02F 1/136; H01L 29/22; H01L 21/34

(52) U.S. Cl. 349/43; 257/43; 438/104; 257/E29.094; 257/E21.46

(57) ABSTRACT

A display substrate, a display device including the display substrate, and a method of fabricating the display substrate are provided. The display substrate includes a gate electrode; a gate-insulating layer disposed on the gate electrode; an oxide semiconductor pattern disposed on the gate-insulating layer; a source electrode disposed on the oxide semiconductor pattern; and a drain electrode disposed on the oxide semiconductor pattern and separated from the source electrode, wherein at least one portion of at least one of the gate-insulating layer or the oxide semiconductor pattern is plasma-processed.

This application claims priority to Korean Patent Application No. 10-2007-0137605, filed on Dec. 26, 2007, and all the benefits accruing therefrom under 35 U.S.C. §119, the contents of which in its entirety are herein incorporated by reference.

### BACKGROUND OF THE INVENTION

1. Field of the Invention

The present invention relates to a display substrate, a display device including the display substrate and a method of fabricating the display substrate. More particularly, the present invention relates to a display substrate, a display device including the display substrate and a method of fabricating the display substrate having stable and reliable thin-film transistors (“TFTs”)

2. Description of the Related Art

In recent years, the demand for the development of large-scale, high-quality display devices has steadily grown. In particular, the demand has been stronger than ever for improving the operating characteristics of thin-film transistors (“TFTs”) for driving liquid crystal displays (“LCDs”). LCDs are just one type of a display device. Conventional TFTs include semiconductor patterns formed of hydrogenated amorphous silicon (“a-Si:H”). However, TFTs formed of a-Si:H generally have low electron mobility.

Techniques for forming semiconductor patterns of an oxide with high electron mobility have been recently developed. However, the operating characteristics of TFTs having an oxide semiconductor pattern are very likely to vary based on the oxygen concentration of the oxide semiconductor pattern.

### BRIEF SUMMARY OF THE INVENTION

One aspect of the present invention provides a display substrate having stable and reliable thin-film transistors (“TFTs”).

Another aspect of the present invention also provides a display device including a display substrate having stable and reliable TFTs.

Yet another aspect of the present invention also provides a method of fabricating a display substrate having stable and reliable TFTs.

However, the aspects of the present invention are not restricted to the ones set forth above. The above and other aspects of the present invention will become more apparent to one of ordinary skill in the art to which the present invention pertains by referencing the detailed description of the present invention given below.

According to an aspect of the present invention, there is provided a display substrate including: a gate electrode; a gate-insulating layer disposed on the gate electrode; an oxide semiconductor pattern disposed on the gate-insulating layer; a source electrode disposed on the oxide semiconductor pattern; and a drain electrode disposed on the oxide semiconductor pattern and separated from the source electrode, wherein at least one portion of the gate-insulating layer and oxide semiconductor pattern is plasma-processed.

According to another aspect of the present invention, there is provided a display device including: a first display substrate which includes a gate electrode, a gate-insulating layer disposed on the gate electrode, an oxide semiconductor pattern disposed on the gate-insulating layer, a source electrode disposed on the oxide semiconductor pattern, and a drain electrode disposed on the oxide semiconductor pattern and separated from the source electrode, at least one portion of the gate-insulating layer and the oxide semiconductor pattern being plasma-processed; a second display substrate which faces the first display substrate; and a liquid crystal layer interposed between the first display substrate and the second display substrate.

According to another aspect of the present invention, there is provided a method of fabricating a display substrate, the method including: forming a gate electrode; forming a gate-insulating layer on the gate electrode; performing a first plasma-processing operation on at least one portion of the gate-insulating layer; and forming a stack of an oxide semiconductor pattern, a source electrode and a drain electrode on the at least one portion of the gate-insulating layer, the drain electrode being separated from the source electrode.

### BRIEF DESCRIPTION OF THE DRAWINGS

The above and other aspects, features and advantages of the present invention will become more apparent by describing in further detail exemplary embodiments thereof with reference to the attached drawings in which:

FIG. 1 illustrates a plan view layout of a display substrate according to an exemplary embodiment of the present invention;

FIG. 2 illustrates a cross-section view taken along line II-II′ of FIG. 1;

FIGS. 3A through 5B illustrate graphs of source-drain current relative to gate voltage for explaining operating characteristics of a thin film transistor (“TFT”) illustrated in FIG. 2;

FIGS. 6 through 11 illustrate cross-section views of a display substrate during fabrication thereof for explaining a method of fabricating the display substrate according to an exemplary embodiment of the present invention;

FIG. 12 illustrates a cross-section view of an another display substrate according to an alternative exemplary embodiment of FIGS. 6 through 11;

FIGS. 13A through 13D illustrate graphs of source-drain current relative to gate voltage for explaining a plasma-processing operation;

FIG. 14 illustrates a cross-section view of a display substrate according to another alternative exemplary embodiment of the present invention; and

FIG. 15 illustrates a cross-section view of a display substrate according to yet another alternative embodiment of the present invention.

### DETAILED DESCRIPTION OF THE INVENTION

The present invention will now be described more fully with reference to the accompanying drawings, in which exemplary embodiments of the present invention are illustrated. Aspects, advantages and features of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the present invention to those skilled in the art, as defined by the appended claims. Like reference numerals refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

In the exemplary embodiments of the present invention, a display device is a liquid crystal display (“LCD”). However, the present invention is not restricted to this.

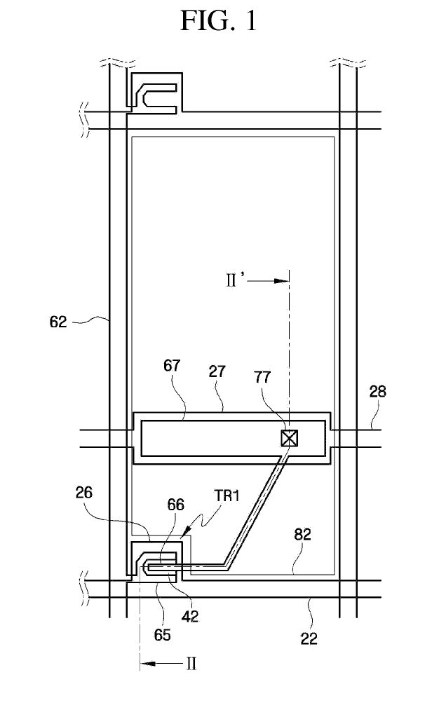

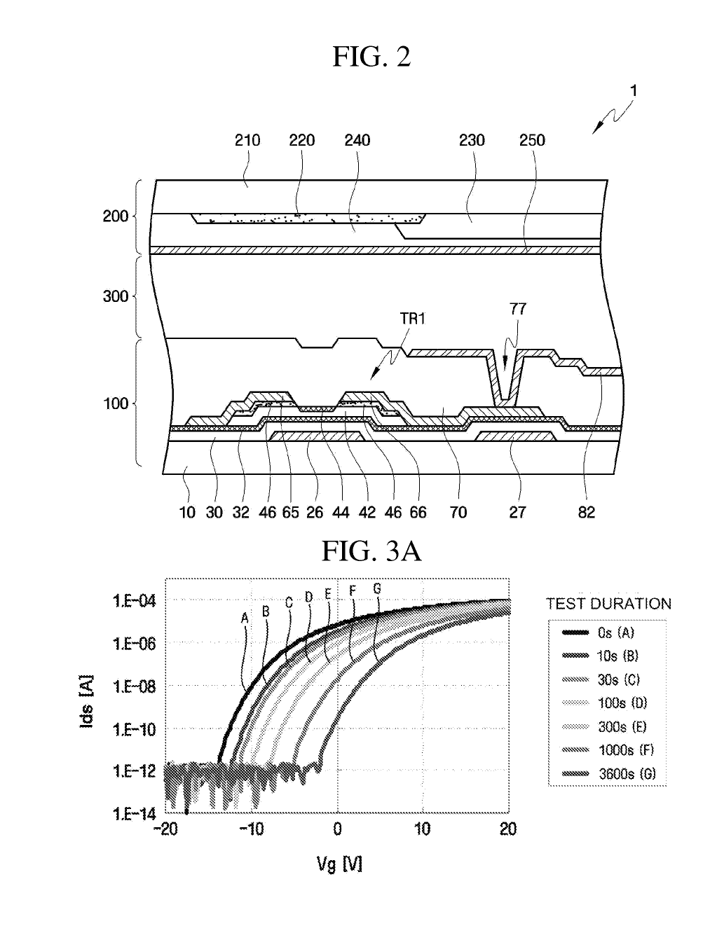

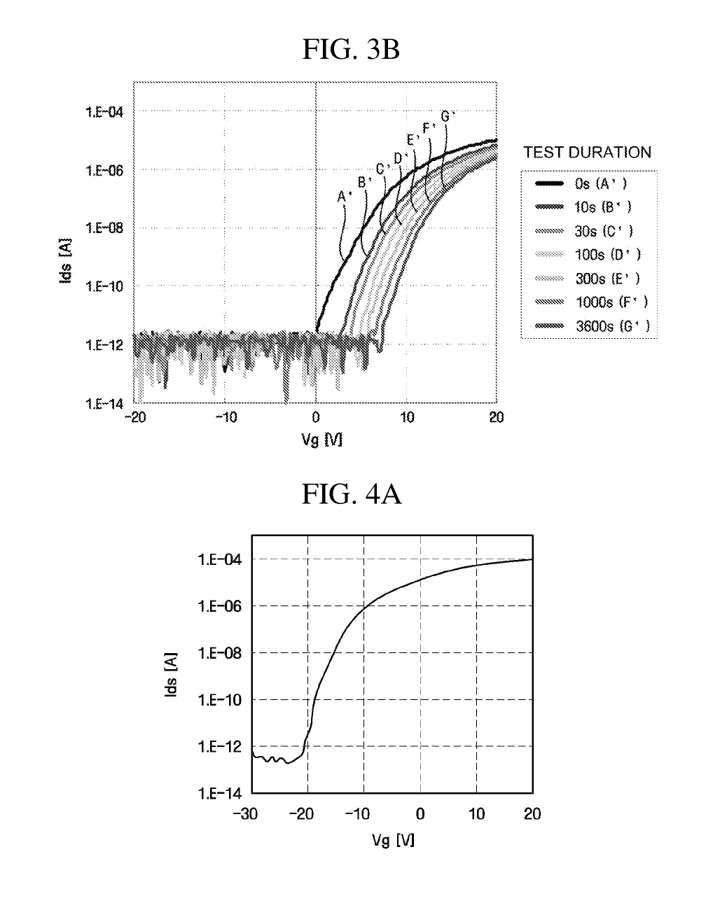

A display substrate according to an exemplary embodiment of the present invention and a display device including the display substrate will hereinafter be described in further detail with reference to FIGS. 1 through 5B. FIG. 1 illustrates a plan view layout of a display substrate according to an exemplary embodiment of the present invention, FIG. 2 illustrates a cross-section view taken along line II-II′ of FIG. 1, and FIGS. 3A through 5B illustrate graphs of source-drain current relative to gate voltage for explaining operating characteristics of a TFT TR1 illustrated in FIG. 2.

Referring to FIGS. 1 and 2, a display device 1 includes a first display substrate 100, a second display substrate 200 and a liquid crystal layer 300 disposed therebetween. For clarity, only the first display substrate 100 is illustrated in FIG. 1.

The structure of the first display substrate 100 will hereinafter be described in further detail. A gate line 22 is horizontally formed on an insulating substrate 10. A gate electrode 26 of the TFT TR1 is formed as a protrusion on the insulating substrate 10 and is connected to the gate line 22. The gate line 22 and the gate electrode 26 are collectively referred to as a gate interconnection.

A storage electrode line 28 is formed on the insulating substrate 10. The storage electrode line 28 extends across a pixel region in parallel with the gate line 22. A storage electrode 27 is connected to the storage electrode line 28. The width of the storage electrode 27 is greater than the width of the storage electrode line 28. The storage electrode 27 overlaps a drain electrode expansion 67 to which a pixel electrode 82 is connected. The storage electrode 27 and the drain electrode expansion 67 constitute a storage capacitor for improving the charge storage capability of a pixel. The storage electrode 27 and the storage electrode line 28 are collectively referred to as a storage interconnection.

The shape and the arrangement of the storage interconnection (27 and 28) may be varied in alternative embodiments. For example, if the pixel electrode 82 and the gate line 22 generate sufficient storage capacitance by overlapping each other, the storage interconnection (27 and 28) may not be formed.

Each of the gate interconnection (22 and 26) and the storage interconnection (27 and 28) may include an aluminum (Al)-based metal such as Al or an Al alloy, a silver (Ag)-based metal such as Ag or an Ag alloy, a copper (Cu)-based metal such as Cu or a Cu alloy, a molybdenum (Mo)-based metal such as Mo or a Mo alloy, chromium (Cr), titanium (Ti) or tantalum (Ta). Each gate interconnection (22 and 26) and storage interconnection (27 and 28) may have a multilayered structure including two conductive layers (not shown) having different physical properties. One of the two conductive layers of each gate interconnection (22 and 26) and storage interconnection (27 and 28) may include a metal with low resistivity, such as an Al-based metal, an Ag-based metal or a Cu-based metal, and may thus be able to reduce a signal delay or a voltage drop. The other conductive layer of each gate interconnection (22 and 26) and storage interconnection (27 and 28) may include a material having excellent bonding properties to indium tin oxide (ITO) or indium zinc oxide (IZO) such as a Mo-based metal, Cr, Ti, or Ta. For example, each gate interconnection (22 and 26) and the storage interconnection (27 and 28) may include a lower layer formed of Cr and an upper layer formed of Al. Alternatively, each gate interconnection (22 and 26) and storage interconnection (27 and 28) may include a lower layer formed of Al and an upper layer formed of Mo. However, the present invention is not restricted to this. That is, each gate interconnection (22 and 26) and storage interconnection (27 and 28) may include various metals or conductive materials other than those set forth herein.

A gate-insulating layer 30 is formed on the gate interconnection (22 and 26) and the storage interconnection (27 and 28). An oxide layer 32 is formed on the gate-insulating layer 30. The gate-insulating layer 30 may include a dielectric material such as silicon nitride (“SiNx”). The oxide layer 32 may be formed by oxidizing the surface of the gate-insulating layer 30. For example, the oxide layer 32 may be formed by oxidizing the surface of the gate-insulating layer 30 using a N₂O or O₂ plasma. The gate-insulating layer 30 may include silicon oxide (e.g., “SiO₂”). The oxide layer 32 prevents or effectively reduces a variation in the oxygen concentration of an oxide semiconductor pattern 42. For example, the oxide layer 32 prevents or effectively reduces a variation in the oxygen concentration of the oxide semiconductor pattern 42 by preventing or effectively reducing the reaction of oxygen originating from the gate-insulating layer 30 with oxygen originating from the oxide semiconductor pattern 42. It is thus possible to improve the operating characteristics of the TFT TR1 by preventing or effectively reducing a variation in the oxygen concentration of the oxide semiconductor pattern 42 with the use of the oxide layer 32. The physical properties of a TFT TR1 having the oxide layer 32 will be described later in further detail with reference to FIGS. 3A through 5B by comparison with a TFT having no such oxide layer.

The oxide semiconductor pattern 42 is formed on the gate-insulating layer 30 and overlaps the gate electrode 26. The oxide semiconductor pattern 42 may include an oxide of one selected from zinc (Zn), indium (In), gallium (Ga), stannum (Sn) and a combination thereof. For example, the oxide semiconductor pattern 42 may include InZnO, lnGaO, InSnO, ZnSnO, GaSnO, GaZnO, or GaInZnO. At least one portion of the oxide semiconductor pattern 42, e.g., a portion 44, is plasma-processed using a N₂O plasma or an O₂ plasma. The plasma-processed portion 44 may include oxygen (O₂). The plasma-processed portion 44 may be exposed by a source electrode 65 and a drain electrode 66. The plasma-processed portion 44 prevents or effectively reduces a variation in the oxygen concentration of the oxide semiconductor pattern 42. More specifically, the plasma-processed portion 44 prevents or effectively reduces a variation in the oxygen concentration of the oxide semiconductor pattern 42 by preventing or effectively reducing the oxide semiconductor pattern 42 from being exposed to the air. Therefore, it is possible to improve the physical properties of the TFT TR1 by preventing or effectively reducing a variation in the oxygen concentration of the oxide semiconductor pattern 42 with the use of the plasma-processed portion 44. The properties of a TFT TR1 having the plasma-processed portion 44 will be described later in further detail with reference to FIGS. 3A through 5B by comparison with a TFT not having a plasma-processed portion.

A data interconnection (62, 65, 66 and 67) is formed on the oxide semiconductor pattern 42 and the gate-insulating layer 30. The data interconnection (62, 65, 66 and 67) includes a data line 62 which extends vertically (as illustrated in FIG. 1) and defines a pixel by intersecting the gate line 22; a source electrode 65 which branches off from the data line 62 and extends over the oxide semiconductor pattern 42 toward the plasma-processed portion 44; a drain electrode 66 which is separated from the source electrode 65, is formed on the oxide semiconductor pattern 42, and faces the source electrode 65; and a drain electrode expansion 67 which extends from the drain electrode 66, overlaps the storage electrode 27 and has a large width.

The data interconnection (62, 65, 66 and 67) may be placed in contact with the oxide semiconductor pattern 42, and may thus constitute an ohmic contact along with the oxide semiconductor pattern 42. For this, the data interconnection (62, 65, 66 and 67) may include a single layer or a multiple layer of nickel (Ni), cobalt (Co), Ti, Ag, Cu, Mo, Al, Be, beryllium (Be), niobium (Nb), gold (Au), iron (Fe), selenium (Se), Ta or a combination thereof. For example, the data interconnection (62, 65, 66 and 67) may include a double layer of Ta/Al, Ta/Al, Ni/Al, Co/Al, or Mo (or a Mo alloy)/Cu or a triple layer of Ti/Al/Ti, Ta/Al/Ta, Ti/Al/TiN, Ta/Al/TaN, Ni/Al/Ni, or Co/Al/Co. However, the present invention is not restricted to this. Referring to FIG. 2, the data interconnection (62, 65, 66 and 67) may not be placed in contact with the oxide semiconductor pattern 42. In this case, the display device 1 may also include ohmic contact layers 46 which are interposed between the data interconnection (62, 65, 66 and 67) and the oxide semiconductor pattern 42, and particularly, between the data interconnection (62, 65, 66 and 67) and the source electrode 65 and between the data interconnection (62, 65, 66 and 67) and the drain electrode 66, and this will hereinafter be described in further detail.

The source electrode 65 partially overlaps the gate electrode 26. The drain electrode 66 also partially overlaps the gate electrode 26 and faces the source electrode 65, as illustrated in FIG. 2. The gate electrode 26, the oxide semiconductor pattern 42, the source electrode 65 and the drain electrode 66 constitute the TFT TR1.

The drain electrode expansion 67 overlaps the storage electrode 27 and constitutes a storage capacitor along with the storage electrode 27 and the gate-insulating layer 30, which is interposed between the drain electrode expansion 67 and the storage electrode 27. If the storage electrode 27 is not provided, the drain electrode expansion 27 may not be formed.

A passivation layer 70 is formed on the data interconnection (62, 65, 66 and 67) and the oxide semiconductor pattern 42. For example, the passivation layer 70 may include an inorganic material such as silicon nitride or silicon oxide, an organic material with excellent planarization properties and photosensitivity, or a dielectric material with a low dielectric constant such as a-Si:C:O or a-Si:O:F obtained by plasma enhanced chemical vapor deposition (“PECVD”).

A contact hole 77 is formed in the passivation layer 70. The drain electrode expansion 67 is exposed through the contact hole 77.

The pixel electrode 82 is formed on the passivation layer 70, conforming to the shape of a pixel. The pixel electrode 82 is electrically connected to the drain electrode expansion 67 through the contact hole 77. The pixel electrode 82 may include a transparent conductive material such as ITO or IZO or a reflective conductive material such aluminum (Al).

The second display substrate 200 will hereinafter be described in further detail. A black matrix 220, which prevents light leakage, is formed on an insulating substrate 210. The black matrix 220 may be formed on the entire surface of the insulating substrate 210, except for portions corresponding to the pixel electrode 82, and may thus define a pixel region. The black matrix 220 may include an opaque organic material or an opaque metal, but is not restricted thereto.

A color filter 230 is formed on the insulating substrate 210. In order to render a color display, the color filter 230 may include red, green or blue color filters. The color filter 230 may be colored red, green and blue and may thus be able to render red, green and blue colors by transmitting or absorbing red light, green light and blue light. The color filter 230 may render various colors by mixing red light, green light and blue light using an additive mixing method.

An overcoat layer 240 is formed on the black matrix 220 and the color filter 230. The overcoat layer 240 reduces the step difference between the black matrix 220 and the color filter 230 and provides a planarized surface. The overcoat 240 may include a transparent organic material. The overcoat 240 may be provided for protecting the color filter 230 and the black matrix 220 and insulating the color filter 230 and the black matrix 220 from a common electrode 250.

The common electrode 250 is formed on the overcoat layer 240. The common electrode 250 may include a transparent conductive material such as ITO or IZO, but is not restricted thereto.

The liquid crystal layer 300 is interposed between the first display substrate 100 and the second display substrate 200. The transmittance of the liquid crystal layer 300 varies according to a difference between the voltage of the pixel electrode 82 and the voltage of the common electrode 250.

The properties of the TFT TR1 of the first display substrate 100 will hereinafter be described in further detail with reference to FIGS. 3A through 5B.

FIG. 3A illustrates a graph of relationships between drain-source current measurement results (Ids) and gate voltage measurements (Vg) of a TFT according to Comparative Example 1, which has a gate-insulating layer and an oxide semiconductor pattern both yet to be plasma-processed, for various test durations. FIG. 3B illustrates a graph of relationships between drain-source current measurement results (Ids) and gate voltage measurement results (Vg) of the TFT TR1 of the first display substrate 100 illustrated in FIG. 2 for various test durations. The drain-source current measurement results (Ids) and the gate voltage measurements (Vs) of FIGS. 3A and 3B were obtained by applying voltages of 20 V and 10 V to the gate electrode and the source electrode, respectively, of each TFT according to Comparative Example 1 and TFT TR1. The oxide semiconductor pattern of the TFT according to Comparative Example 1 and the oxide semiconductor pattern 42 of the TFT TR1 both include GaInZnO and have a channel length-to-channel width ratio (L/W) of 25/4.

TABLE 1

| | Threshold Voltage | Threshold Voltage |
|---|---|---|
| | (V) of TFT Not | (V) of TFT |
| Time (s) | Plasma-Processed | Plasma-Processed |
| 0 | 3.906 | 11.160 |
| 10 | 4.273 | 11.862 |
| 30 | 4.751 | 12.181 |
| 100 | 5.221 | 12.646 |
| 300 | 6.352 | 13.029 |
| 1000 | 7.659 | 13.361 |
| 3600 | 9.152 | 13.601 |
| Difference | 5.246 (= 9.152 − 3.906) | 2.441 (= 13.601 − 11.160) |

Referring to FIG. 3A and Table 1, the threshold voltage of the TFT according to Comparative Example 1 considerably varies according to the duration of a test. Specifically, when the duration of a test is 0 s, the threshold voltage of the TFT according to Comparative Example 1 is 3.906 V. In contrast, when the duration of a test is 3600 s, the threshold voltage of the TFT according to Comparative Example 1 is 9.152 V, which is 5.246 V higher than the threshold voltage of the TFT according to Comparative Example 1 when the duration of a test is 0 s.

Referring to FIG. 3B, since the gate-insulating layer 30 and the oxide semiconductor pattern 42 of the TFT TR1 of the first display substrate 100 are plasma-processed, the threshold voltage of the TFT TR1 varies, but less considerably than the TFT according to Comparative Example 1, according to the duration of a test. Specifically, when the duration of a test is 0 s, the threshold voltage of the TFT TR1 is 11.160 V. In contrast, when the duration of a test is 3600 s, the threshold voltage of the TFT TR1 is 13.601 V, which is 2.441 V higher than that of the TFT TR1 when the duration of a test is 0 s.

That is, referring to FIGS. 3A and 3B, the threshold voltage of the TFT TR1 varies less severely than the threshold voltage of the TFT according to Comparative Example 1, and thus, the TFT TR1 is deemed more stable than the TFT according to Comparative Example 1.

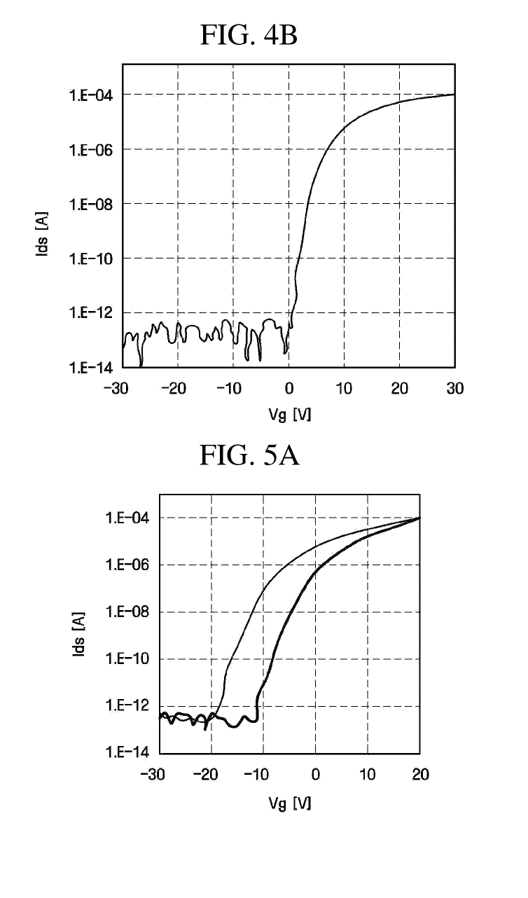

FIG. 4A illustrates a graph of a relationship between drain-source current measurement results (Ids) and gate voltage measurements (Vg) of the TFT according to Comparative Example 1, which has a gate-insulating layer and an oxide semiconductor pattern both yet to plasma-processed, and FIG. 4B illustrates a graph of a relationship between drain-source current measurement results (Ids) and gate voltage measurement results (Vg) of the TFT TR1 of the first display substrate 100 illustrated in FIG. 2. The source-drain current measurement results (Ids) and the gate voltage measurement results (Vg) of FIGS. 4A and 4B were obtained by applying a voltage of 10 V to the source electrode of the TFT according to Comparative Example 1 and to the source electrode 65 of the TFT TR1.

Referring to FIGS. 4A and 4B, the TFT according to Comparative Example 1 is turned off when the gate voltage Vg is about −20 V, whereas the TFT TR1 is turned off when the gate voltage Vg is about 0 V. Thus, according to the exemplary embodiment of FIG. 2, it is possible to reduce the operating voltage range of a TFT, and thus to reduce the power consumption of a TFT.

FIG. 5A illustrates a graph of the hysteresis of a drain-source current (Ids) of the TFT according to Comparative Example 1, which has a gate-insulating layer and an oxide semiconductor pattern both yet to plasma-processed, and FIG. 5B illustrates a graph of the hysteresis of a drain-source current (Ids) of the TFT TR1 of the first display substrate 100 illustrated in FIGS. 1 and 2. The drain-source current measurement results (Ids) of FIGS. 5A and 5B were obtained by applying a voltage of 10 V to the source electrode of the TFT according to Comparative Example 1 and to the source electrode 65 of the TFT TR1 at room temperature, gradually increasing the gate voltages of the TFT according to Comparative Example 1 and the TFT TR1 from −30 V to 20 V and then reducing the gate voltages of the TFT according to Comparative Example 1 and the TFT TR1 from 20 V to −30V.

Referring to FIGS. 5A and 5B, when the drain-source current Ids is I.E-12, the gate voltage Vg of the TFT according to Comparative Example 1 varies by about 10 V. In contrast, when the drain-source current Ids is I.E-12, the gate voltage Vg of the TFT TR1 varies only by about 3 V.

In short, the TFT TR1 is more stable and reliable than the TFT according to Comparative Example 1. Therefore, according to the exemplary embodiment of FIG. 2, it is possible to reduce the operating voltage range of a TFT and thus reduce the power consumption of a TFT.

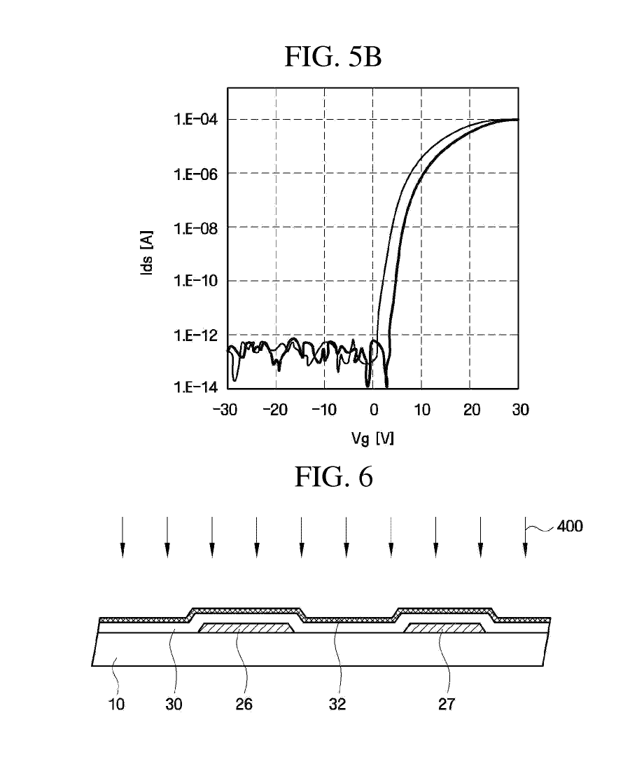

A method of fabricating a display substrate according to an exemplary embodiment of the present invention will hereinafter be described in further detail with reference to FIGS. 1, 2 and 6 through 11. FIGS. 6 through 11 illustrate cross-section views of a display substrate during fabrication thereof for explaining a method of fabricating the first display substrate 100 illustrated in FIG. 2, according to an exemplary embodiment of the present invention.

Referring to FIG. 6, a multiple metal layer (not shown) for forming a gate interconnection is deposited on an insulating substrate 10. Thereafter, the multiple metal layer is patterned, thereby forming a gate line 22, a gate electrode 26 and a storage electrode 27. Each gate line 22, gate electrode 26 and storage electrode 27 may have a double layer including a lower layer formed of Al or an Al alloy and an upper layer formed of Mo or a Mo alloy. The lower and upper layers of each gate line 22, gate electrode 26 and storage electrode 27 may be formed using a sputtering method. The multiple metal layer may be patterned using a wet etching method or a dry etching method. More specifically, the multiple metal layer may be patterned using a wet etching method and phosphoric acid, nitric acid or acetic acid as an etchant. Alternatively, the multiple metal layer may be patterned using a dry etching method (more particularly, an anisotropic dry etching method) and using a chlorine-based etching gas, for example, Cl₂ or BCI₃. In this case, it is possible to precisely pattern the multiple metal layer.

A gate-insulating layer 30 is deposited on the insulating substrate 10, the gate interconnection (22 and 26) and the storage interconnection (27 and 28), for example, using a PECVD method or a reactive sputtering method.

Thereafter, an oxide layer 32 is formed on the gate-insulating layer 30 by processing the surface of the gate-insulating layer 30 with a N₂O or O₂ plasma, as indicated by reference numeral 400. The surface of the gate-insulating layer 30 may be either entirely or partially plasma-processed using the N₂O or O₂ plasma.

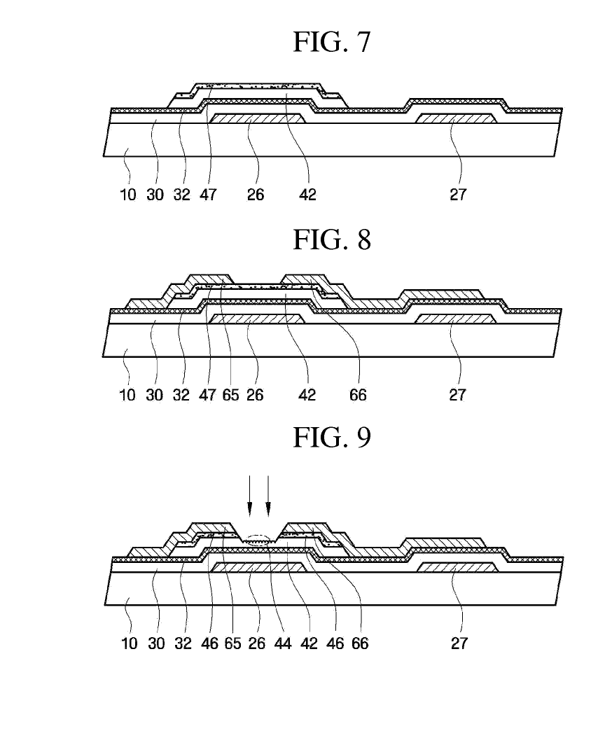

Thereafter, referring to FIG. 7, an oxide semiconductor layer (not shown) and a first conductive layer (not shown) for forming an ohmic contact are sequentially formed on the gate-insulating layer 30, for example, using a sputtering method. Thereafter, the oxide semiconductor layer and the first conductive layer are patterned, thereby forming an oxide semiconductor pattern 42 and a second conductive layer 47 for forming an ohmic contact.

Thereafter, referring to FIG. 8, a conductive layer (not shown) for forming a data interconnection is deposited, for example, using a sputtering method, on the oxide semiconductor pattern 42 and the second conductive layer 47. Thereafter, the conductive layer for forming data interconnection is patterned, thereby forming data interconnection including a data line 62, a source electrode 65, a drain electrode 66, and a drain electrode expansion 67.

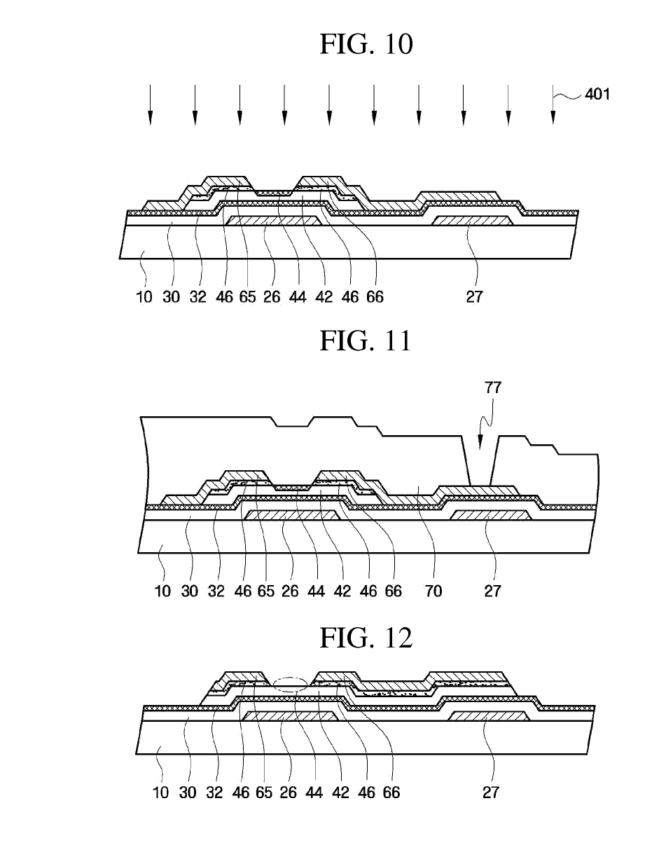

Thereafter, referring to FIG. 9, an etch-back operation is performed on the second conductive layer 47, thereby forming an ohmic contact layer 46 and exposing a plasma-processed portion 44 of the oxide semiconductor pattern 42. The surface of the plasma-processed portion 44 of the oxide semiconductor pattern 42 may be damaged due to being exposed between the source electrode 65 and the drain electrode 66, therefore referring to FIG. 10, the plasma-processed portion 44 of the oxide semiconductor pattern 42 is plasma-processed using a N₂O or O₂ plasma, as indicated by reference numeral 401.

The formation of the oxide semiconductor pattern 42 and the conductive layer for forming the data interconnection (62, 65, 66, and 67) and the processing of the plasma-processed portion 44 of the oxide semiconductor pattern 42 with a N₂O or O₂ plasma may be sequentially performed while continuously maintaining a vacuum atmosphere in a vacuum chamber. Then, it is possible to prevent the oxide semiconductor pattern 42 from being adversely affected by oxygen in the air and thus prevent or effectively reduce a variation in the oxygen concentration of the oxide semiconductor pattern 42. Therefore, it is possible to prevent or effectively reduce the deterioration of the physical properties of a TFT.

The oxide semiconductor pattern 42 may include an oxide of one selected from Zn, In, Ga, Sn and a combination thereof. For example, the oxide semiconductor pattern 42 may include InZnO, InGaO, InSnO, ZnSnO, GaSnO, GaZnO, or GaInZnO. In this case, the data interconnection (62, 65, 66, and 67) may include a metal having a lower work function than that of the oxide semiconductor pattern 42. For example, the data interconnection (62, 65, 66, and 67) may include a single layer or a multiple layer of Co, Ti, Ag, Cu, Mo, Al, Be, Nb, Au, Fe, Se, Ta or a combination thereof. Specifically, the data interconnection (62, 65, 66, and 67) may include a double layer of Ta/Al, Ta/Al, Ni/Al, Co/Al, or Mo (or a Mo alloy)/Cu or a triple layer of Ti/Al/Ti, Ta/Al/Ta, Ti/Al/TiN, Ta/Al/TaN, Ni/AI/Ni, or Co/AI/Co.

Referring to FIG. 11, a passivation layer 70 is formed. Thereafter, photolithography is performed on the passivation layer 70, thereby forming a contact hole 77 through which the drain electrode expansion 67 is exposed (referring to FIG. 1).

Thereafter, referring to FIG. 2, a transparent conductive material such as ITO or IZO or a reflective conductive material is deposited and etched, thereby forming a pixel electrode 82, which is connected to the drain electrode expansion 67.

In the embodiment of FIGS. 6 through 11, the first display substrate 100 is fabricated using five masks. However, the present invention is not restricted to this. That is, the first display substrate 100 may be fabricated using four masks, and this will hereinafter be described in more detail with reference to FIG. 12.

FIG. 12 illustrates a cross-section view of an another display substrate according to an alternative exemplary of the exemplary embodiment of the display substrate illustrated in FIGS. 6 through 11. Referring to FIG. 12, a first display substrate 100 may be fabricated using four masks. That is, an oxide semiconductor layer (not shown), a conductive layer (not shown) for forming an ohmic contact, and a conductive layer (not shown) for forming a data interconnection are sequentially deposited on a gate-insulating layer 30 that has already been plasma-processed. Thereafter, the oxide semiconductor layer, the conductive layer for forming an ohmic contact, and the conductive layer for forming data interconnection are etched using a single etching mask, thereby forming an oxide semiconductor pattern 42, an ohmic contact layer 46 and the data interconnection (65 and 66). Thereafter, a portion 44 of the oxide semiconductor pattern 42, which is exposed by the data interconnection (65 and 66) is plasma-processed.

The embodiment of FIGS. 6 through 11 may be easily applied to a color-filter-on-array (“COA”) structure in which a color filter is formed on a TFT array.

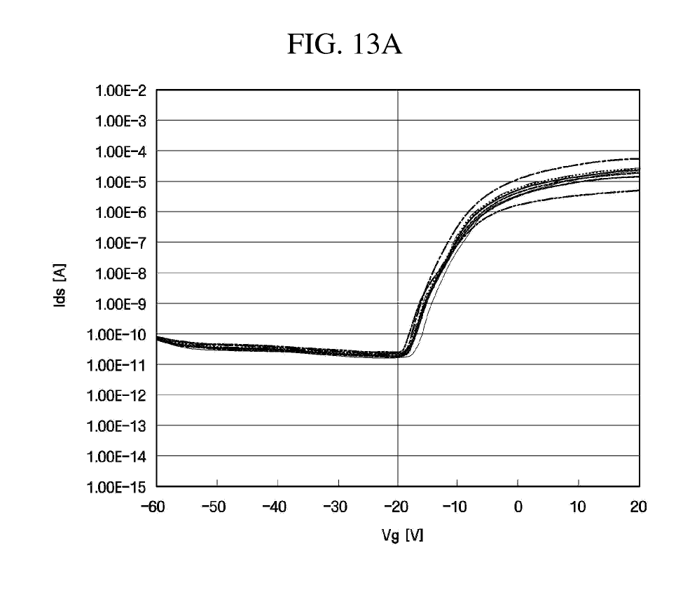

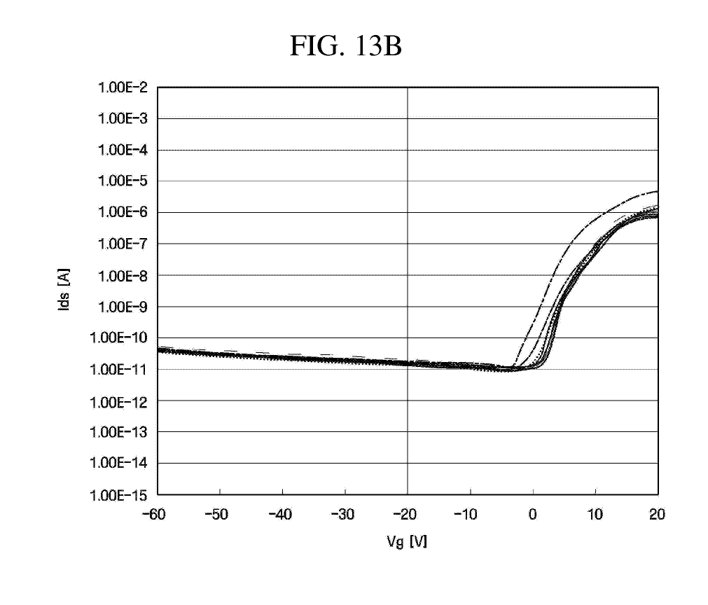

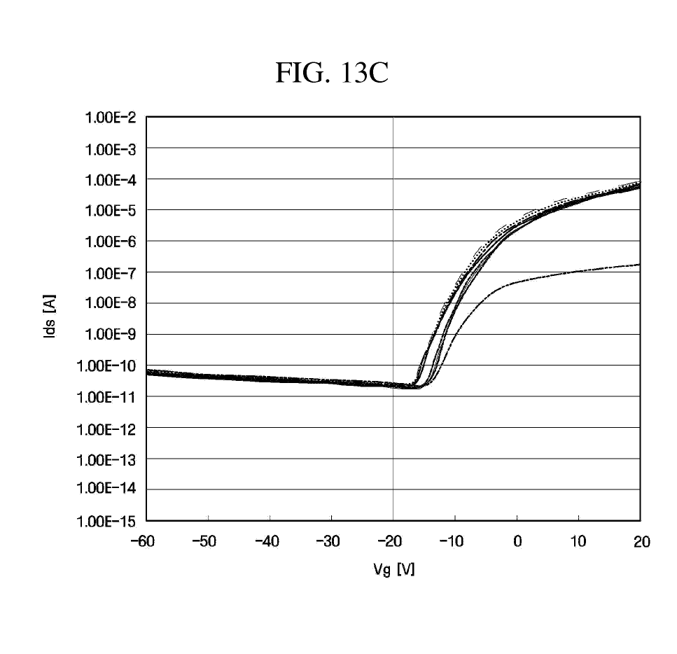

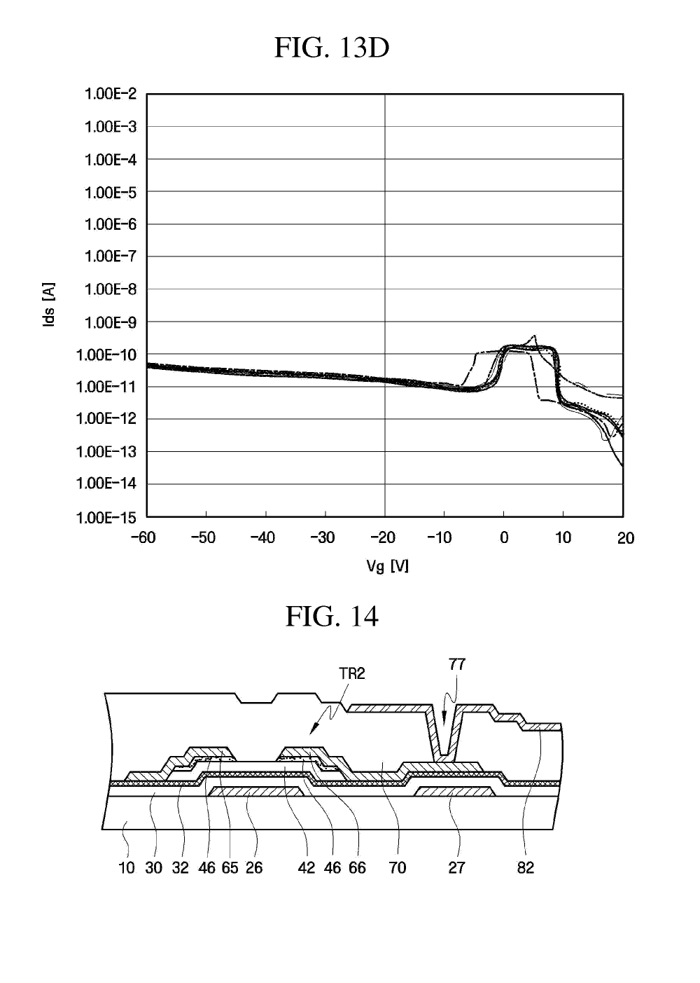

Plasma-processing operations 400 and 401 of FIGS. 6 and 10 will hereinafter be described in further detail with reference to FIGS. 13A through 13D. FIGS. 13A through 13D illustrate graphs of relationships between drain-source current measurement results (Ids) and gate voltage measurement results (Vg) for various plasma processing conditions including radio frequency (“RF”) power, pressure and time.

Specifically, FIG. 13A illustrates a graph for explaining the properties of TFTs obtained by performing each of the plasma-processing operations 400 and 401 for 30 seconds under a pressure of about 1000-3000 mTorr using an RF power source with a power of about 100 mW/cm²·time. FIG. 13B illustrates a graph for explaining the properties of TFTs obtained by performing each of the plasma-processing operations 400 and 401 for 20 seconds under a pressure of about 1000-3000 mTorr using an RF power source with an electric power of about 400 mW/cm²·time. FIG. 13C illustrates a graph for explaining the physical properties of TFTs obtained by performing each of the plasma-processing operations 400 and 401 for 10 seconds under a pressure of about 1000-3000 mTorr using an RF power source with an electric power of about 600 mW/cm²·time. FIG. 13D illustrates a graph for explaining the properties of TFTs obtained by performing each of the plasma-processing operations 400 and 401 for 200 seconds under a pressure of about 1000-3000 mTorr using an RF power source with an electric power of about 600 mW/cm²·time.

Referring to FIG. 13A, TFTs are turned off when the gate voltage Vg is within the range of about −20 V to −17 V. Referring to FIG. 13C, when the gate voltage Vg is 20 V, the drain-source currents Ids of TFTs are discrepant from one another according to the positions of the TFTs disposal on a first display substrate 100, and thus, the physical properties of the TFTs are not uniform. Referring to FIG. 13D, even when the gate voltage Vg is 20 V, TFTs may not be properly turned on. TFTs may be able to be properly turned on only if the gate voltage Vg is 20 V and the drain-source current Ids is higher than 1.00E-06(A). Referring to FIG. 13B, when the gate voltage Vg is about 0 V, TFTs are turned off. The physical properties of the TFTs are generally uniform regardless of the positions of the TFTs on a first display substrate 100. Therefore, the plasma-processing operations 400 and 401 may be performed using an RF power source with a power of 400 mW/cm²·time. However, the present invention is not restricted to this. That is, the plasma-processing operations 400 and 401 may be performed using an RF power source with a power of about 100-600 mWcm²·time. In addition, the plasma-processing operations 400 and 401 may be performed for less than 200 seconds. Moreover, only one of the plasma-processing operations 400 and 401 may be performed under a pressure of 1000-3000 mTorr for less than 200 seconds by using an RF power source with a power of 400 mW/cm²·time.

A display substrate according to another exemplary embodiment of the present invention and a display device including the display substrate will hereinafter be described in further detail with reference to FIG. 14. FIG. 14 illustrates a cross-section view of the display substrate according to the another alternative exemplary embodiment of the present invention. In FIGS. 2 and 14, like reference numerals indicate like elements, and, thus, detailed descriptions thereof will be omitted.

A first display substrate illustrated in FIG. 14 is different from the first display substrate 100 illustrated in FIG. 2 in that an oxide semiconductor pattern 42 does not include any plasma-processed portion. However, in the embodiment of FIG. 14, like that in the embodiment of FIG. 12, it is possible to prevent or effectively reduce a variation in the oxygen concentration of the oxide semiconductor pattern 42 due to the oxide layer 32. For example, the oxide layer 32 prevents or effectively reduces a variation in the oxygen concentration of the oxide semiconductor pattern 42 by preventing or effectively reducing the reaction of oxygen originating from the gate-insulating layer 30 with oxygen originating from the oxide semiconductor pattern 42.

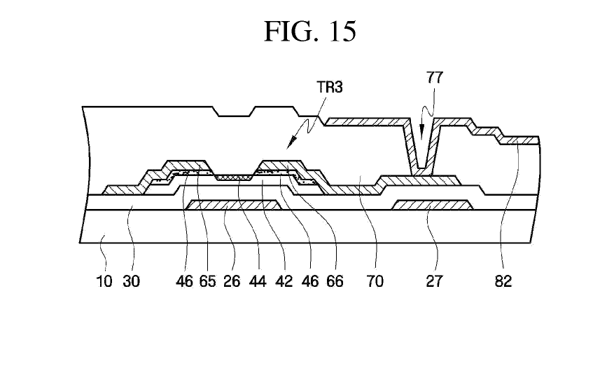

A display substrate according to another alternative exemplary embodiment of the present invention and a display device including the display substrate will hereinafter be described in further detail with reference to FIG. 15. FIG. 15 illustrates a cross-section view of the display substrate according to the another alternative exemplary embodiment of the present invention. In FIGS. 2 and 15, like reference numerals indicate like elements, and, thus, detailed descriptions thereof will be omitted.

The first display substrate illustrated in FIG. 15 is different from the first display substrate 100 illustrated in FIG. 2 in that a gate-insulating layer 30 is not plasma-processed. However, in the embodiment of FIG. 15, like in the embodiment of FIG. 12, it is possible to prevent or effectively reduce a variation in the oxygen concentration of the oxide semiconductor pattern 42 because the plasma-processed portion 44 prevents or effectively reduces the oxide semiconductor pattern 42 from being exposed to the air.

While the present invention has been particularly shown and described with reference to exemplary embodiments thereof, it will be understood by those of ordinary skill in the art that various changes may be made in the form and details without departing from the spirit and scope of the present invention as defined by the following claims.

What is claimed is:

1. A display substrate comprising:
a gate electrode;
a gate-insulating layer disposed on the gate electrode;
an oxide semiconductor pattern disposed on the gate-insulating layer;
a source electrode disposed on the oxide semiconductor pattern; and
a drain electrode disposed on the oxide semiconductor pattern and separated from the source electrode,
wherein at least one portion of at least one of the gate-insulating layer and oxide semiconductor pattern is plasma-processed.

2. The display substrate of claim 1, wherein the at least one portion of the gate-insulating layer is plasma-processed using a N₂O plasma or an O₂ plasma.

3. The display substrate of claim 1, wherein the at least one portion of the gate-insulating layer comprises silicon oxide.

4. The display substrate of claim 1, wherein at least one portion of the oxide semiconductor pattern is plasma-processed.

5. The display substrate of claim 4, wherein the at least one portion of the oxide semiconductor pattern is exposed by the source electrode and the drain electrode.

6. The display substrate of claim 4, wherein the at least one portion of the oxide semiconductor pattern is plasma-processed using a N₂O plasma or an O₂ plasma.

7. A display device comprising:
a first display substrate which comprises a gate electrode, a gate-insulating layer disposed on the gate electrode, an oxide semiconductor pattern disposed on the gate-insulating layer, a source electrode disposed on the oxide semiconductor pattern, and a drain electrode disposed on the oxide semiconductor pattern and separated from the source electrode, at least one portion of at least one of the gate-insulating layer and the oxide semiconductor pattern being plasma-processed;
a second display substrate which faces the first display substrate; and
a liquid crystal layer interposed between the first display substrate and the second display substrate.

8. The display device of claim 7, wherein the at least one portion of the gate-insulating layer is plasma-processed using a N₂O plasma or an O₂ plasma.

9. The display device of claim 7, wherein the at least one portion of the gate-insulating layer comprises silicon oxide.

10. The display device of claim 7, wherein at least one portion of the oxide semiconductor pattern is plasma-processed.

11. The display device of claim 10, further comprising a passivation layer disposed on the first display substrate, wherein the at least one portion of the oxide semiconductor pattern is exposed by the source electrode and the drain electrode and is in contact with the passivation layer.

12. The display device of claim 10, wherein the at least one portion of the oxide semiconductor pattern is plasma-processed using a N₂O plasma or an O₂ plasma.

13. A method of fabricating a display substrate, comprising:
forming a gate electrode;
forming a gate-insulating layer on the gate electrode;
performing a first plasma-processing operation on at least one portion of the gate-insulating layer; and
forming a stack of an oxide semiconductor pattern, a source electrode and a drain electrode on the at least one portion of the gate-insulating layer, the drain electrode being separated from the source electrode.

14. The method of claim 13, further comprising performing a second plasma-processing operation on at least one portion of the oxide semiconductor pattern exposed by the source electrode and the drain electrode.

15. The method of claim 14, wherein the performing of the first plasma-processing operation and the performing of the second plasma-processing operation both comprise performing a plasma-processing operation using a N₂O plasma or an O₂ plasma.

16. The method of claim 13, wherein at least one of the performing of the first plasma-processing operation and the performing of the second plasma-processing operation comprises performing a plasma-processing operation using a radio frequency (RF) power source with a power of about 400 mW/cm²·time.

17. The display device of claim 16, wherein at least one of the performing of the first plasma-processing operation and the performing of the second plasma-processing operation comprises performing a plasma-processing operation under a pressure of about 1000 mTorr to about 3000 mTorr.
